(19) United States
(12) Patent Application Publication
(10) Pub. No.: US 2013/0140583 A1
(43) Pub. Date: Jun. 6, 2013

(54) SILICON CARBIDE SEMICONDUCTOR DEVICE AND METHOD FOR MANUFACTURING THE SAME

(71) Applicant: Sumitomo Electric Industries, Ltd., Osaka-shi (JP)

(72) Inventors: Hideki HAYASHI, Osaka-shi (JP); Takeyoshi MASUDA, Osaka-shi (JP)

(73) Assignee: Sumitomo Electric Industries, Ltd., Osaka-shi (JP)

(21) Appl. No.: 13/667,850

(22) Filed: Nov. 2, 2012

Related U.S. Application Data
(60) Provisional application No. 61/566,447, filed on Dec. 2, 2011.

(30) Foreign Application Priority Data
Dec. 2, 2011 (JP) 2011-264332

(51) Int. Cl. H01L 29/161; H01L 21/337; H01L 21/336

(52) U.S. Cl. 257/77; 438/186; 257/E21.409; 257/E29.084; 257/E21.445

(57) ABSTRACT

First, third, and fourth regions have a first conductivity type, and a second region has a second conductivity type. The second region is provided with a plurality of through holes exposing the first region. The third region includes a contact portion, a connecting portion, and a filling portion. The contact portion is in contact with a first portion of the second region. The connecting portion extends from the contact portion to each of the plurality of through holes in the second region. The filling portion fills each of the plurality of through holes in the second region. The fourth region, is provided on the first portion of the second region.

### BACKGROUND OF THE INVENTION

1. Field of the Invention

The present invention relates to a silicon carbide semiconductor device and a method for manufacturing the same, and in particular to a silicon carbide semiconductor device having a gate electrode and a method for manufacturing the same.

2. Description of the Background Art

“700-V 1.0-mΩ·cm² Buried Gate SiC-SIT (SiC-BGSIT)” by Y. Tanaka et al., IEEE Electron Device Letters, Vol. 27, No. 11 (2006), pp. 908-910 (Non Patent Literature 1) discloses a Static Induction Transistor (SIT), that is, a Junction Field Effect Transistor (JFET). The JFET uses SiC (silicon carbide), is of a vertical type, and, according to this literature, can obtain an extremely low ON resistance. Although this literature mentions that a normally-off type SIT may be implemented by optimization of design, it actually discloses a normally-on type SIT. Generally, in a power semiconductor, normally-off type operation may be desired from the viewpoint of, for example, safety.

“1200V SiC JFET in Cascode Light Configuration: Comparison versus Si and SIC Based Switches” by F. Bjoerk et al., Materials Science Forum, Vols. 679-680 (2011), pp. 587-590 (Non Patent Literature 2) discloses causing a SiC JFET to operate like a normally-off type JFET, using a Si MOSFET (Metal Oxide Semiconductor Field Effect Transistor). Specifically, this literature discloses a configuration in which a SiC JFET and a Si MOSFET are connected in cascode with each other.

In the technique of Non Patent Literature 1, normally-off type operation is not implemented. The technique of Non Patent Literature 2 requires a task of individually forming a JFET chip and a MOSFET chip and thereafter connecting these parts with each other.

### SUMMARY OF THE INVENTION

The present invention has been made to solve problems as described above, and one object of the present invention is to provide a silicon carbide semiconductor device configured as one chip and having both low ON resistance characteristics and normally-off characteristics, and a method for manufacturing the same.

A silicon carbide semiconductor device in accordance with the present invention is a silicon carbide semiconductor device having a silicon carbide substrate having a first surface and a second surface opposite to the first surface, including first to fourth regions, a gate insulating film, a gate electrode, and first and second electrodes. The first region has a first conductivity type, and forms the first surface. The second region has a second conductivity type different from the first conductivity type, and is provided on the first region. The second region includes a first portion forming the second surface and a second portion apart from the second surface. The second region is provided with a plurality of through holes exposing the first region. The third region has the first conductivity type, and includes a contact portion, a connecting portion, and a filling portion. The contact portion is in contact with the first portion of the second region at the second surface. The connecting portion forms the second surface and extends from the contact portion to each of the plurality of through holes in the second region. The filling portion fills each of the plurality of through holes in the second region. The fourth region has the first conductivity type, is provided on the first portion of the second region, is separated from each of the first region and the third region by the first portion of the second region, and forms the second surface. The gate insulating film is provided on a portion between the contact portion of the third region and the fourth region, of the first portion of the second region. The gate electrode is provided on the gate insulating film. The first electrode is electrically insulated from the gate electrode and is in contact with each of the first portion of the second region and the fourth region. The second electrode is in contact with the first surface formed by the first region.

According to the above device, the semiconductor device can be configured as one chip by using one silicon carbide substrate. Further, both low ON resistance characteristics and normally-off characteristics can be obtained.

Preferably, in the above device, the first region may include a drift layer having an impurity concentration lower than that of the third region. Thereby, breakdown voltage can be increased.

Preferably, in the above device, the first region may include a base layer being in contact with the second electrode and having an impurity concentration higher than that of the third region. Thereby, a contact resistance between the first region and the first electrode can be reduced.

Preferably, in the above device, the second surface may have a reverse mesa shape including a side wall surface formed by the first portion of the second region. Thereby, orientation of the second surface formed by the first portion of the second region can be adjusted by selecting an inclination of the side wall surface.

Preferably, in the above device, the second surface formed by the first portion may include either one of a {0-33-8} plane and a {0-11-4} plane in a hexagonal crystal structure. Thereby, carrier mobility along the second surface formed by the first portion is improved. Thus, the ON resistance of the semiconductor device can be reduced.

Preferably, in the above device, the connecting portion of the third region may include a low-resistivity layer having an impurity concentration higher than that of the filling portion of the third region. Thereby, the connecting portion has a low electrical resistance. Thus, the ON resistance of the semiconductor device can be further reduced.

A method for manufacturing a silicon carbide semiconductor device in accordance with the present invention includes the steps of: preparing a first region having a first conductivity type and having a first surface and a surface opposite to the first surface; forming a second region having a second conductivity type different from the first conductivity type on the surface of the first region opposite to the first surface, the second region including a first portion and a second portion, the second region being provided with a plurality of through holes exposing the first region; forming a third region having the first conductivity type and covering the second region to fill each of the plurality of through holes; etching the second region and the third region partially such that the first portion of the second region is exposed while the second portion of the second region is kept covered with the third region, and such that a surface formed by the second region and the third region forms a reverse mesa shape including a side wall surface formed by the first portion of the second region; forming a fourth region having the first conductivity type and separated from each of the first region and the third region by the first portion of the second region, on the first portion of the second region, after the step of etching; forming a gate insulating film on the first portion of the second region forming the side wall surface of the reverse mesa shape; forming a gate electrode on the gate insulating film; forming a first electrode electrically insulated from the gate electrode and in contact with each of the first portion of the second region and the fourth region; and forming a second electrode on the first surface of the first region.

According to the above manufacturing method, the semiconductor device can be configured as one chip by using one silicon carbide substrate. Further, both low ON resistance characteristics and normally-off characteristics can be obtained.

Preferably, in the above manufacturing method, the step of etching may be performed by thermal etching. Thereby, a smooth surface formed by the first portion of the second region can be exposed. Thus, the gate insulating film formed on the surface has an improved reliability. Consequently, a portion of the silicon carbide semiconductor device that is switched by an insulating gate can have an improved reliability.

As described above, according to the present invention, a semiconductor device can be configured as one chip by using one silicon carbide substrate. In addition, both low ON resistance characteristics and normally-off characteristics can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view schematically showing a configuration of a silicon carbide semiconductor device in Embodiment 1 of the present invention.

FIG. 2 is a plan view schematically showing a configuration of a silicon carbide substrate of the silicon carbide semiconductor device of FIG. 1.

FIG. 3 is a schematic cross sectional view taken along a line in FIG. 1.

FIG. 4 is an enlarged fragmentary view of FIG. 3.

FIG. 5 is a view showing a current path when the silicon carbide semiconductor device of FIG. 1 is in an ON state.

FIG. 6 is a view schematically showing an equivalent circuit of the silicon carbide semiconductor device of FIG. 1.

FIG. 7 is a cross sectional view schematically showing a first step of a method for manufacturing the silicon carbide semiconductor device in Embodiment 1 of the present invention.

FIG. 8 is a cross sectional view schematically showing a second step of the method for manufacturing the silicon carbide semiconductor device in Embodiment 1 of the present invention.

FIG. 9 is a cross sectional view schematically showing a third step of the method for manufacturing the silicon carbide semiconductor device in Embodiment 1 of the present invention.

FIG. 10 is a cross sectional view schematically showing a fourth step of the method for manufacturing the silicon carbide semiconductor device in Embodiment 1 of the present invention.

FIG. 11 is a cross sectional view schematically showing a fifth step of the method for manufacturing the silicon carbide semiconductor device in Embodiment 1 of the present invention.

FIG. 12 is a cross sectional view schematically showing a sixth step of the method for manufacturing the silicon carbide semiconductor device in Embodiment 1 of the present invention.

FIG. 13 is a cross sectional view schematically showing a seventh step of the method for manufacturing the silicon carbide semiconductor device in Embodiment 1 of the present invention.

FIG. 14 is a cross sectional view schematically showing an eighth step of the method for manufacturing the silicon carbide semiconductor device in Embodiment 1 of the present invention.

FIG. 15 is a cross sectional view schematically showing a ninth step of the method for manufacturing the silicon carbide semiconductor device in Embodiment 1 of the present invention.

FIG. 16 is a cross sectional view schematically showing a tenth step of the method for manufacturing the silicon carbide semiconductor device in Embodiment 1 of the present invention.

FIG. 17 is a cross sectional view schematically showing an eleventh step of the method for manufacturing the silicon carbide semiconductor device in Embodiment 1 of the present invention.

FIG. 18 is a cross sectional view schematically showing a configuration of a silicon carbide semiconductor device in Embodiment 2 of the present invention.

FIG. 19 is a cross sectional view schematically showing one step of a method for manufacturing the silicon carbide semiconductor device in Embodiment 2 of the present invention.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly. Regarding crystallographic indications in the present specification, an individual plane is represented by ( ) and a group plane is represented by { }. To indicate a negative index of a plane, a negative symbol is put before a numeral instead of putting “-” (bar) above the numeral. For description of an angle, a system in which an omnidirectional angle is 360° is employed.

### Embodiment 1

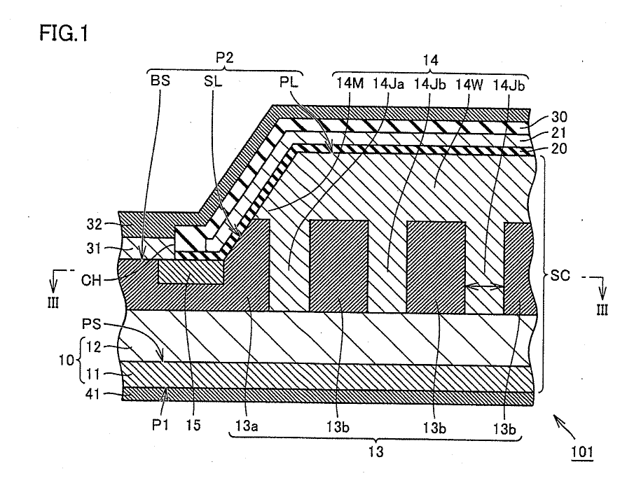

As shown in FIG. 1, a switching device 101 (a silicon carbide semiconductor device) in the present embodiment includes an epitaxial substrate SC (a silicon carbide substrate), a gate insulating film 20, a gate electrode 21, an interlayer insulating film 30, a source electrode 31 (a first electrode), a source wire 32, and a drain electrode 41 (a second electrode).

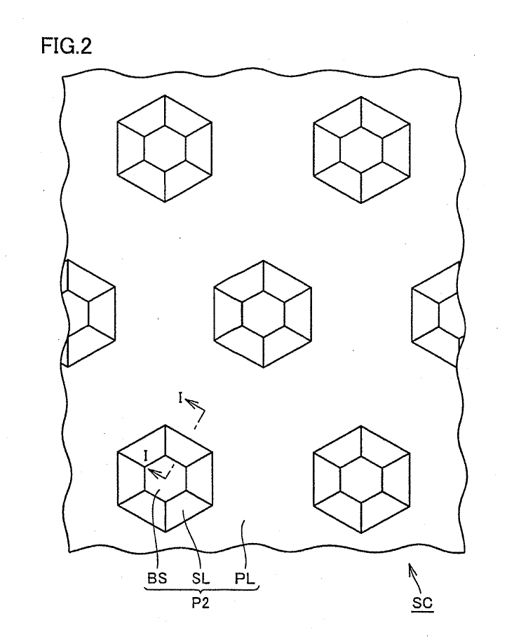

Epitaxial substrate SC is made of silicon carbide. In the present embodiment, epitaxial substrate SC has a hexagonal crystal structure, and preferably has a polytype of 4H. Epitaxial substrate SC includes a first region 10, a second region 13, a third region 14, and a fourth region 15. Further, epitaxial substrate SC has a backside surface P1 (a first surface) and an upper surface P2 (a second surface opposite to the first surface). Backside surface P1 has a flat shape. Upper surface P2 forms a reverse mesa shape (FIG. 2) having a recessed surface BS, a side wall surface SL, and a top surface PL. Recessed surface BS and top surface PL are parallel to backside surface P1, and side wall surface SL is inclined with respect to backside surface P1.

As shown in FIG. 2, recessed surface BS of the reverse mesa shape in the present embodiment has a hexagonal outer edge, and, for example, has a regular hexagonal outer edge. Six side wall surfaces SL are provided to be connected to six sides of the hexagonal outer edge, respectively. When silicon carbide having a hexagonal crystal structure having six-fold symmetry is used, side wall surfaces SL surrounding recessed surface BS can have plane orientations crystallographically equivalent to each other, by using such a reverse mesa shape.

First region 10 has n type (a first conductivity type). First region 10 forms backside surface P1 of epitaxial substrate SC. First region 10 has a single crystal substrate 11 (a base layer) forming backside surface P1, and a drift layer 12 provided thereon. Single crystal substrate 11 has an impurity concentration higher than that of third region 14. A surface PS of single crystal substrate 11 opposite to backside surface P1 preferably has a plane orientation of {000-1}, and more preferably has a plane orientation of (000-1). Drift layer 12 has an impurity concentration lower than that of third region 14. Single crystal substrate 11 has an impurity concentration of, for example, 5×10¹⁸/cm³. Drift layer 12 has an impurity concentration of, for example, 1×10¹⁶/cm³.

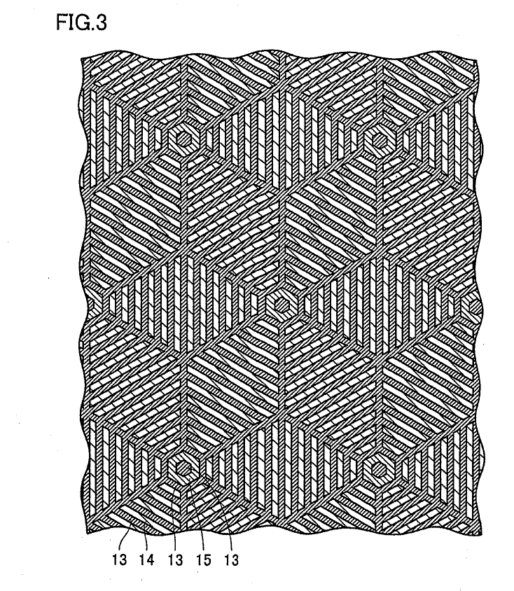

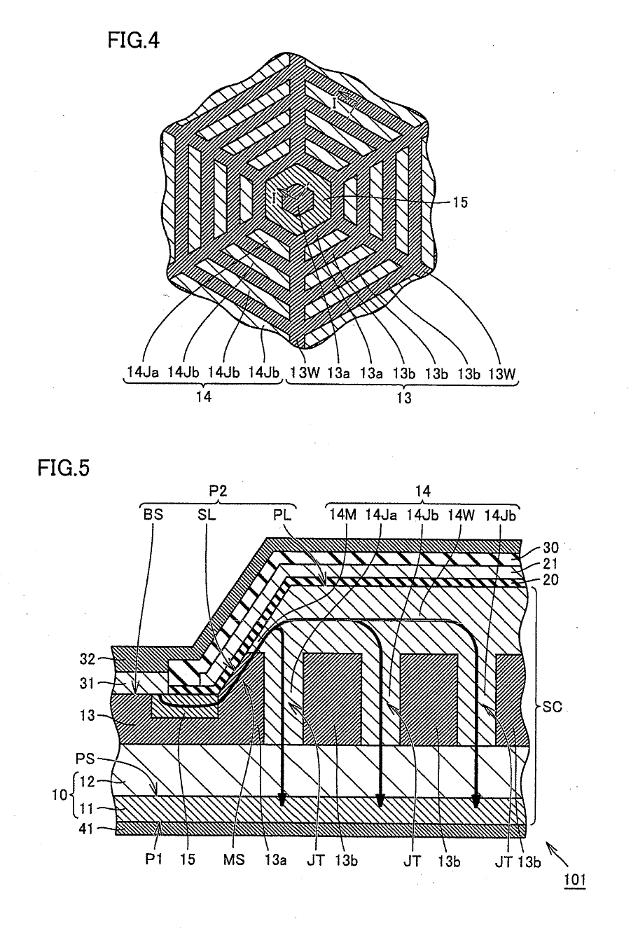

Second region 13 has p type (a second conductivity type different from the first conductivity type). Second region 13 is provided on first region 10. Second region 13 is provided with a plurality of through holes exposing first region 10, and second region 13 includes an exposed portion 13a (a first portion), a buried gate portion 13b (a second portion), and a coupling portion 13W (see FIGS. 3 and 4). Exposed portion 13a partially forms each of recessed surface BS and side wall surface SL of upper surface P2 of epitaxial substrate SC. Buried gate portion 13b is apart from upper surface P2. In other words, buried gate portion 13b is buried in epitaxial substrate SC relative to upper surface P2. Coupling portion 13W couples between exposed portion 13a and buried gate portion 13b. Second region 13 has an impurity concentration of, for example, 5×10¹⁷/cm³.

Upper surface P2 formed by exposed portion 13a preferably includes either one of a {0-33-8} plane and a {0-11-4} plane in a hexagonal crystal structure, and more preferably includes either one of a (0-33-8) plane and a (0-11-4) plane. Here, in a case where upper surface P2 formed by exposed portion 13a includes a {0-33-8} plane, upper surface P2 formed by exposed portion 13a may correspond to a composite plane made of a microscopic {0-33-8} plane and another microscopic plane. When viewed macroscopically, the composite plane is preferably a {0-11-2} plane, and more preferably a (0-11-2) plane.

Preferably, in planar view, as shown in FIG. 4, exposed portion 13a has a hexagonal outer edge, and, for example, has a regular hexagonal outer edge. Buried gate portions 13b extending in a hexagonal shape surround exposed portion 13a in a multiple manner. Further, coupling portions 13W radially extending from exposed portion 13a couple these structures with each other.

Third region 14 has n type. Third region 14 includes a contact portion 14M, a connecting portion 14W, and filling portions 14Ja, 14Jb. Contact portion 14M partially forms side wall surface SL of upper surface P2 of epitaxial substrate SC, and is in contact with exposed portion 13a of second region 13 at side wall surface SL of upper surface P2. Connecting portion 14W partially forms upper surface P2, and forms top surface PL of upper surface P2. In addition, connecting portion 14W extends from contact portion 14M to each of the plurality of through holes in second region 13. Filling portions 14Ja and 14Jb fill the plurality of through holes in second region 13, respectively. Filling portion 14Ja fills a through hole provided between exposed portion 13a and buried gate portion 13b, and filling portion 14Jb fills a through hole provided between buried gate portions 13b. Third region 14 has an impurity concentration of for example, 1×10¹⁷/cm³.

Fourth region 15 has n type. Fourth region 15 is provided on exposed portion 13a of second region 13, and is separated from each of first region 10 and third region 14 by exposed portion 13a of second region 13. Further, fourth region 15 partially forms upper surface P2. More specifically, fourth region 15 partially forms recessed surface BS of upper surface P2.

Gate insulating film 20 is provided on a portion between contact portion 14M of third region 14 and fourth region 15, of exposed portion 13a of second region 13. Gate insulating film 20 is made of, for example, silicon oxide. Gate electrode 21 is provided on gate insulating film 20. Interlayer insulating film 30 covers gate electrode 21, and has a contact hole CH on recessed surface BS of upper surface P2 of epitaxial substrate SC. Contact hole CH exposes each of exposed portion 13a of second region 13 and fourth region 15. Source electrode 31 is an ohmic electrode that is in contact with each of exposed portion 13a of second region 13 and fourth region 15 in contact hole CH. Source electrode 31 is electrically insulated from gate electrode 21. Source wire 32 is in contact with source electrode 31, and is insulated from gate electrode 21 by interlayer insulating film 30. Drain electrode 41 is an ohmic electrode that is in contact with backside surface P1 formed by single crystal substrate 11 of first region 10.

Next, an operation of switching device 101 will be described.

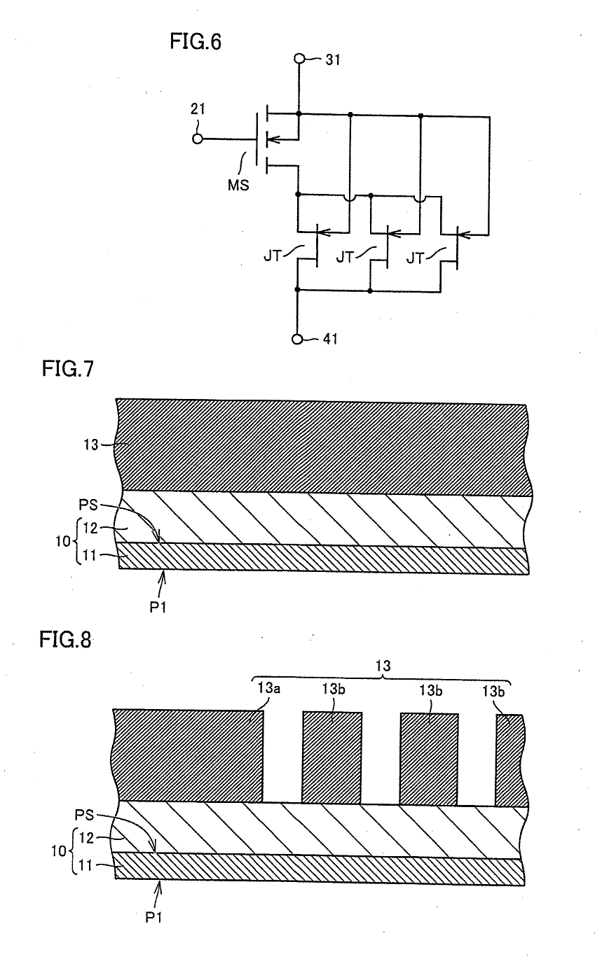

As shown in FIG. 5, switching device 101 has a MOS portion MS and a JFET portion JT. MOS portion MS is a MOS structure in which a flow of a carrier using side wall surface SL formed by exposed portion 13a as a channel surface can be controlled by a potential of gate electrode 21. JFET portion JT is a WET structure in which a flow of a carrier using filling portion 14Jb as a channel can be controlled by a potential of buried gate portion 13b. In the present embodiment, filling portion 14Ja between exposed portion 13a and buried gate portion 13b can also serve as a channel for JFET portion JT. These MOS portion MS and JFET portions JT form a structure equivalent to a cascode circuit shown in FIG. 6. Thereby, switching device 101 can quickly switch current flow as indicated by arrows in FIG. 5 by the potential of gate electrode 21, and has a low ON resistance.

Next, a method for manufacturing switching device 101 will be described.

Referring to FIG. 7, drift layer 12 is formed on surface PS of n type single crystal substrate 11 by epitaxial growth of n type silicon carbide. Thereby, first region 10 having n type and having backside surface P1 and a surface opposite to backside surface P1 is prepared. Then, second region 13 is formed on the surface of first region 10 opposite to backside surface P1 by epitaxial growth of p type silicon carbide. The epitaxial growth of the silicon carbides can be performed, for example, by Chemical Vapor Deposition (CVD).

Referring to FIG. 8, second region 13 is patterned, thereby forming second region 13 including exposed portion 13a, buried gate portion 13b, and coupling portion 13W (now shown in FIG. 8; see FIG. 4) and provided with the plurality of through holes exposing first region 10. The patterning can be performed, for example, by photolithography and Reactive Ion Etching (RIB).

Referring to FIG. 9, third region 14 covering second region 13 is formed to fill each of the through holes described above by epitaxial growth of n type silicon carbide. Thereby, epitaxial substrate SC having upper surface P2 is formed.

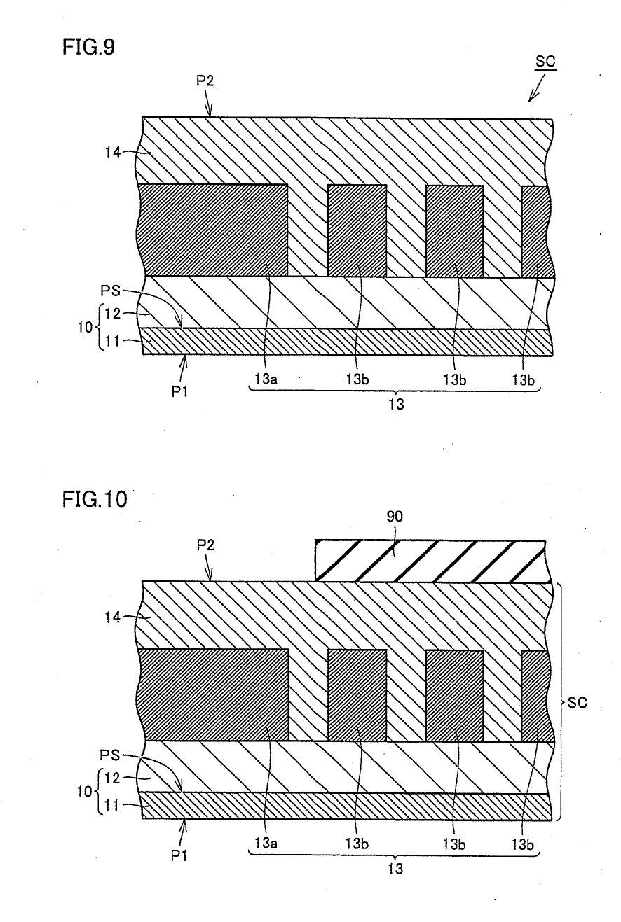

Referring to FIG. 10, a mask layer 90 is formed on third region 14 to cover a portion of upper surface P2 that will serve as top surface PL (FIG. 1). Mask layer 90 is made of, for example, silicon oxide. When silicon oxide is used, etching selectivity with respect to epitaxial substrate SC can be extremely increased.

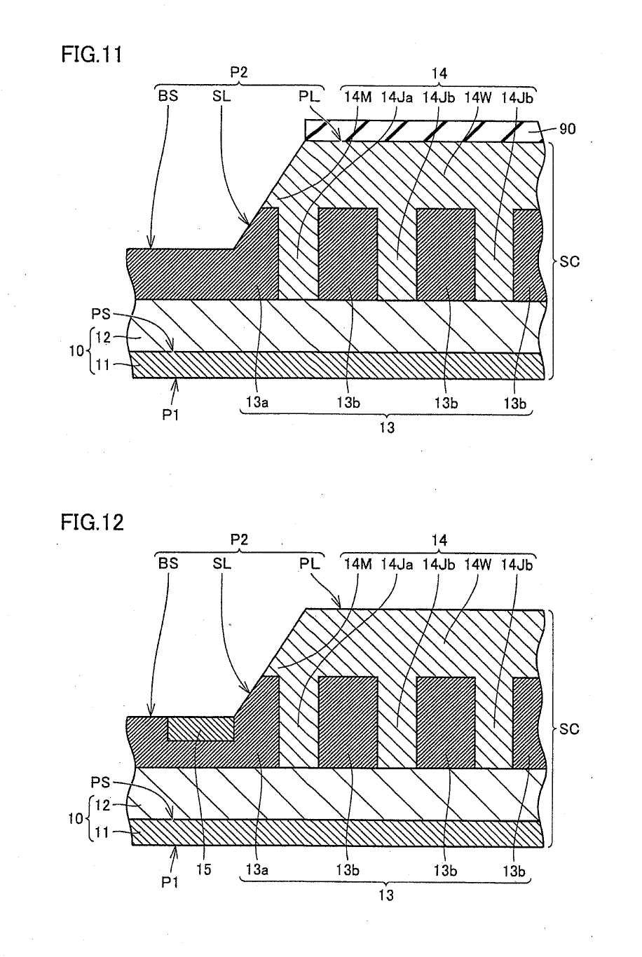

Referring to FIG. 11, second region 13 and third region 14 are partially etched. The etching is performed such that exposed portion 13a of second region 13 is exposed while buried gate portion 13b of second region 13 is kept covered with third region 14. Further, the etching is performed such that a surface formed by second region 13 and third region 14 forms the reverse mesa shape including side wall surface SL formed by exposed portion 13a. By the etching, upper surface P2 having recessed surface BS, side wall surface SL, and top surface PL is formed.

In the present embodiment, the etching is performed by thermal etching. Here, the thermal etching is performed by exposing an object to be etched to an etching gas at a high temperature, and substantially has no physical etching action. By using the thermal etching, side wall surface SL including the {0-33-8} plane or the {0-11-4} plane can be spontaneously formed.

Process gas for the thermal etching in the present embodiment contains halogen atoms. More preferably, the halogen atoms are chlorine atoms, and in this case, the process gas contains, for example, Cl₂ gas. Instead of or in addition to the chlorine atoms, the process gas may contain fluorine atoms, and in this case, the process gas contains, for example, carbon tetrafluoride or sulfur hexafluoride. Preferably, the process gas further contains a gas containing oxygen atoms, in addition to a gas containing a halogen element. The gas containing oxygen atoms is, for example, O₂ gas. It should be noted that the process gas may contain a carrier gas. As the carrier gas, for example, nitrogen (N₂) gas, argon gas, or helium gas can be used.

Preferably, heat treatment temperature in the thermal etching is not less than 700° C. and not more than 1200° C. The lower limit of this temperature is more preferably 800° C., further preferably 900° C. Further, the upper limit of this temperature is more preferably 1100° C., further preferably 1000° C. In this case, etching rate can be of a sufficiently practical value. When the heat treatment temperature is set to not less than 700° C. and not more than 1000° C., a rate of etching SiC is, for example, approximately 70 μm/hr.

Referring further to FIG. 12, mask layer 90 described above is removed. In addition, fourth region 15 having n type and separated from each of first region 10 and third region 14 by exposed portion 13a of second region 13 is formed on exposed portion 13a of second region 13. The formation of fourth region 15 can be performed, for example, by an ion implantation method.

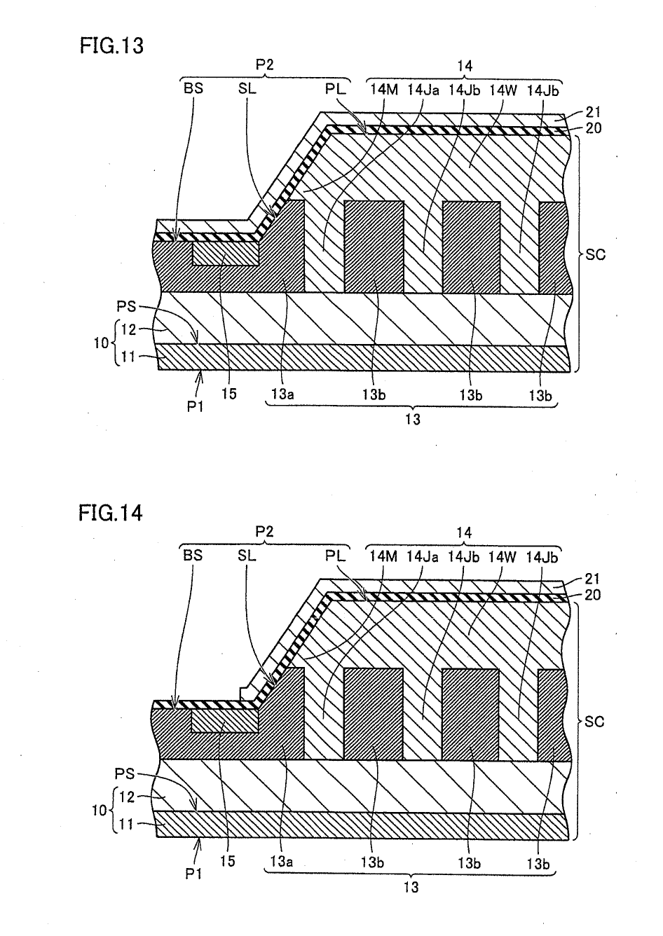

Referring to FIG. 13, gate insulating film 20 is formed on upper surface P2. This formation can be performed, for example, by forming a thermally oxidized film by thermal oxidation of upper surface P2. As a result, gate insulating film 20 is formed on exposed portion 13a forming side wall surface SL. Subsequently, gate electrode 21 is formed on gate insulating film 20.

Referring to FIG. 14, gate electrode 21 is patterned. Thereby, a portion of gate insulating film 20 is exposed.

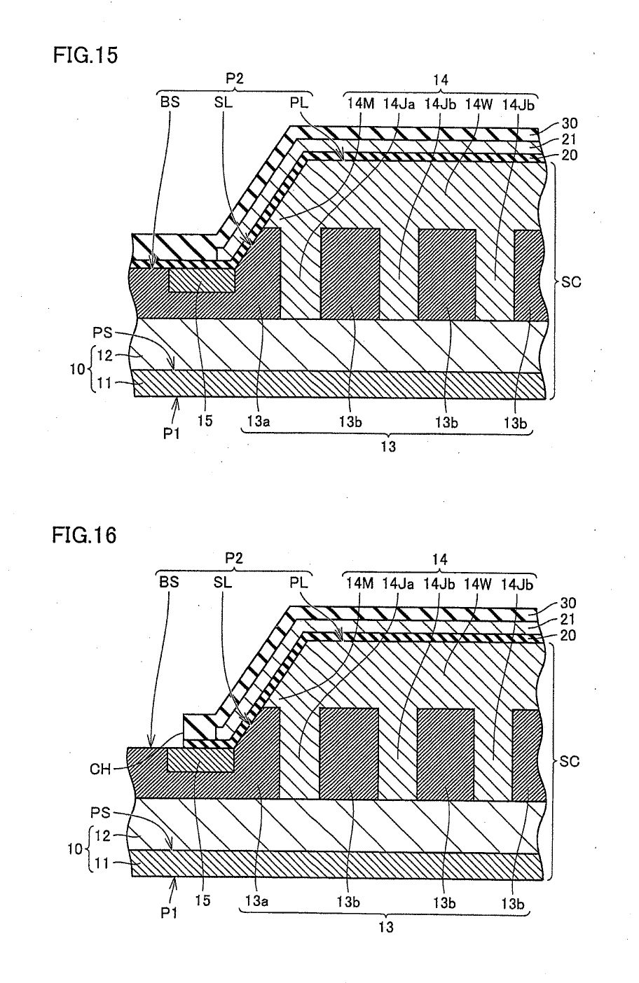

Referring to FIG. 15, interlayer insulating film 30 is formed on the exposed gate insulating film and gate electrode 21.

Referring to FIG. 16, contact hole CH penetrating interlayer insulating film 30 and gate insulating film 20 is formed to expose each of exposed portion 13a and fourth region 15 forming recessed surface BS.

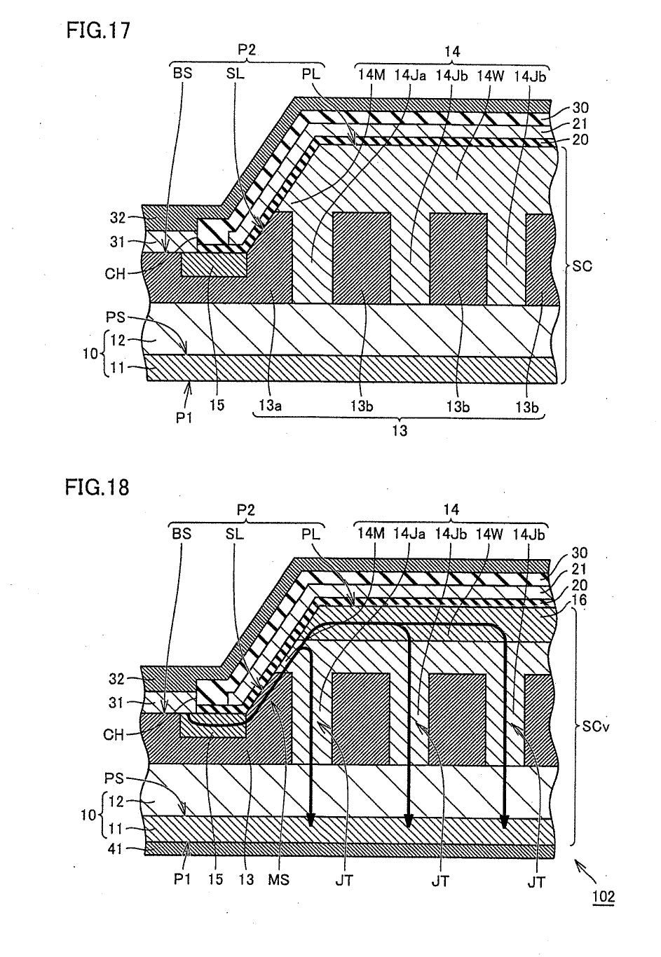

Referring to FIG. 17, the source electrode is formed on recessed surface BS of upper surface P2 exposed by contact hole CH. Thereby, source electrode 31 electrically insulated from gate electrode 21 and in contact with each of exposed portion 13a and fourth region 15 is formed. In addition, source wire 32 is formed.

Referring to FIG. 1 again, switching device 101 is obtained by forming drain electrode 41 on backside surface P1 of first region 10.

According to the present embodiment, switching device 101 can be configured as one chip by using one epitaxial substrate SC. Further, both low ON resistance characteristics and normally-off characteristics can be obtained.

Further, first region 10 includes drift layer 12 having an impurity concentration lower than that of third region 14. Thereby, switching device 101 can have an increased breakdown voltage.

Further, first region 10 includes single crystal substrate 11 being in contact with drain electrode 41 and having an impurity concentration higher than that of third region 14. Thereby, a contact resistance between first region 10 and source electrode 31 can be reduced.

Further, upper surface P2 has a reverse mesa shape including side wall surface SL formed by exposed portion 13a of second region 13. Thereby, orientation of upper surface P2 formed by exposed portion 13a of second region 13 can be adjusted by selecting an inclination of side wall surface SL.

Further, upper surface P2 formed by exposed portion 13a preferably includes either one of a {0-33-8} plane and a {0-11-4} plane in a hexagonal crystal structure. Thereby, carrier mobility along upper surface P2 formed by exposed portion 13a is improved. Thus, the ON resistance of switching device 101 can be reduced. Further, the step of etching for forming side wall surface SL is performed by thermal etching. Thereby, a smooth surface formed by exposed portion 13a of second region 13 can be exposed. Thus, gate insulating film 20 formed on the surface has an improved reliability. Consequently, a portion of switching device 101 that is switched by an insulating gate can have an improved reliability.

Further, when n type is used as the first conductivity type as in the present embodiment, electrons are used as a carrier, and thus carrier mobility can be improved. However, p type may be used as the first conductivity type. In other words, a configuration in which “n type” and “p type” in the configuration described above are reversed may be used.

Although the thermal etching method is used in the present embodiment, a dry etching method or wet etching method other than that may be used.

### Embodiment 2

Referring to FIG. 18, a switching device 102 (a silicon carbide semiconductor device) in the present embodiment has an epitaxial substrate SCv (a silicon carbide substrate). In epitaxial substrate SCv, connecting portion 14W of third region 14 includes a low-resistivity layer 16 having an impurity concentration higher than that of filling portions 14Ja, 14Jb.

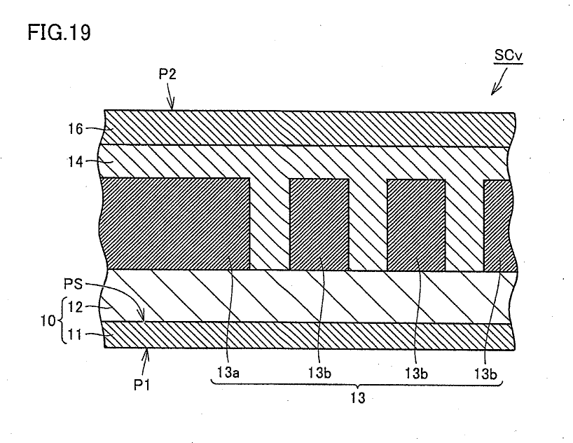

Next, a method for manufacturing switching device 102 will be described. Firstly, the steps identical to those shown in FIGS. 7 to 9 in the manufacturing method described in Embodiment 1 are performed. Then, low-resistivity layer 16 is formed as shown in FIG. 19. Thereby, epitaxial substrate SCv is formed. Thereafter, the steps identical to those from the step in FIG. 10 in Embodiment 1 are performed, and thereby the switching device (FIG. 18) is obtained.

It should be noted that, other than the foregoing, the configuration of Embodiment 2 is substantially the same as that of Embodiment 1 described above. Thus, the same or corresponding elements are given the same characters and are not described repeatedly.

According to the present embodiment, connecting portion 14W has a low electrical resistance. Thus, the ON resistance of switching device 102 can be further reduced.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device having a silicon carbide substrate having a first surface and a second surface opposite to said first surface, comprising:
a first region having a first conductivity type, included in said silicon carbide substrate, and forming said first surface;
a second region having a second conductivity type different from said first conductivity type, included in said silicon carbide substrate, and provided on said first region, said second region including a first portion forming said second surface and a second portion apart from said second surface, said second region being provided with a plurality of through holes exposing said first region;
a third region having said first conductivity type, included in said silicon carbide substrate, and including a contact portion, a connecting portion, and a filling portion, said contact portion being in contact with said first portion of said second region at said second surface, said connecting portion forming said second surface and extending from said contact portion to each of said plurality of through holes in said second region, said filling portion filling each of said plurality of through holes in said second region;
a fourth region having said first conductivity type, included in said silicon carbide substrate, provided on said first portion of said second region, separated from each of said first region and said third region by said first portion of said second region, and forming said second surface;
a gate insulating film provided on a portion between said contact portion of said third region and said fourth region, of said first portion of said second region;
a gate electrode provided on said gate insulating film;
a first electrode electrically insulated from said gate electrode and in contact with each of said first portion of said second region and said fourth region; and
a second electrode in contact with said first surface formed by said first region.

2. The silicon carbide semiconductor device according to claim 1, wherein said first region includes a drift layer having an impurity concentration lower than that of said third region.

3. The silicon carbide semiconductor device according to claim 1, wherein said first region includes a base layer being in contact with said second electrode and having an impurity concentration higher than that of said third region.

4. The silicon carbide semiconductor device according to claim 1, wherein said second surface has a reverse mesa shape including a side wall surface formed by said first portion of said second region.

5. The silicon carbide semiconductor device according to claim 1, wherein said second surface formed by said first portion includes either one of a {0-33-8} plane and a {0-11-4} plane in a hexagonal crystal structure.

6. The silicon carbide semiconductor device according to claim 1, wherein said connecting portion of said third region includes a low-resistivity layer having an impurity concentration higher than that of said filling portion of said third region.

7. A method for manufacturing a silicon carbide semiconductor device, comprising the steps of:
preparing a first region having a first conductivity type and having a first surface and a surface opposite to said first surface;
forming a second region having a second conductivity type different from said first conductivity type on the surface of said first region opposite to said first surface, said second region including a first portion and a second portion, said second region being provided with a plurality of through holes exposing said first region;
forming a third region having said first conductivity type and covering said second region to fill each of said plurality of through holes;
etching said second region and said third region partially such that said first portion of said second region is exposed while said second portion of said second region is kept covered with said third region, and such that a surface formed by said second region and said third region forms a reverse mesa shape including a side wall surface formed by said first portion of said second region;
forming a fourth region having said first conductivity type and separated from each of said first region and said third region by said first portion of said second region, on said first portion of said second region, after said step of etching;
forming a gate insulating film on said first portion of said second region forming said side wall surface of said reverse mesa shape;
forming a gate electrode on said gate insulating film;
forming a first electrode electrically insulated from said gate electrode and in contact with each of said first portion of said second region and said fourth region; and
forming a second electrode on said first surface of said first region.

8. The method for manufacturing a silicon carbide semiconductor device according to claim 7, wherein said step of etching is performed by thermal etching.
